(19) United States
(12) Patent Application Publication
(10) Pub. No.: US 2024/0324385 A1
(43) Pub. Date: Sep. 26, 2024

(54) COLOR CONVERSION SUBSTRATE AND DISPLAY DEVICE INCLUDING THE SAME

(71) Applicant: Samsung Display Co., LTD., Yongin-si (KR)

(72) Inventors: KEUNWOO PARK, Yongin-si (KR); TAEHOON KIM, Yongin-si (KR); DANBI YANG, Yongin-si (KR); KANGSEOB JEONG, Yongin-si (KR)

(21) Appl. No.: 18/526,913

(22) Filed: Dec. 1, 2023

(30) Foreign Application Priority Data
Mar. 20, 2023 (KR) 10-2023-0036045

(51) Int. Cl. H10K 59/38; H10K 59/122; H10K 59/88

(52) U.S. Cl. CPC H10K 59/38; H10K 59/122; H10K 59/88

(57) ABSTRACT

A color conversion substrate includes: a base substrate, a bank layer disposed under the base substrate and defining a pixel opening and a dummy opening adjacent to the pixel opening, a color conversion layer disposed in the pixel opening of the bank layer, a spacer disposed under the bank layer, and an auxiliary layer disposed in the dummy opening of the bank layer, including the same material as the spacer, and having a thickness smaller than a thickness of the bank layer.

This application claims priority to Korean Patent Application No. 10-2023-0036045, filed on Mar. 20, 2023, and all the benefits accruing therefrom under 35 U.S.C. § 119, the content of which in its entirety is herein incorporated by reference.

### BACKGROUND

### 1. Technical Field

Embodiments provide generally to a display device. More particularly, embodiments relate to a color conversion substrate and the display device including the same.

### 2. Description of the Related Art

A display device is a device that displays an image to provide visual information to a user. The display device may include a color conversion substrate including a color conversion layer and a color filter layer and an array substrate including a plurality of pixels.

A sealing member and a filling layer may be disposed between the color conversion substrate and the array substrate. The sealing member may couple the color conversion substrate and the array substrate, and the filling layer may fill a gap between the color conversion substrate and the array substrate.

### SUMMARY

Embodiments provide a color conversion substrate with improved manufacturing efficiency.

Embodiments provide a display device including the color conversion substrate.

A color conversion substrate according to embodiments of the present disclosure includes: a base substrate; a bank layer disposed under the base substrate and defining a pixel opening and a dummy opening adjacent to the pixel opening; a color conversion layer disposed in the pixel opening of the bank layer; a spacer disposed under the bank layer; and an auxiliary layer disposed in the dummy opening of the bank layer, including the same material as the spacer, and having a thickness smaller than a thickness of the bank layer.

In an embodiment, the thickness of the auxiliary layer may be smaller than a thickness of the color conversion layer.

In an embodiment, each of the spacer and the auxiliary layer may include an organic photoresist material.

In an embodiment, the color conversion substrate may further include a color filter layer disposed between the base substrate and the bank layer and a low-refractive index layer disposed between the color filter layer and the bank layer.

A display device according to embodiments of the present disclosure includes: a first base substrate: a bank layer disposed under the first base substrate and defining a pixel opening and a dummy opening adjacent to the pixel opening; a color conversion layer disposed in the pixel opening of the bank layer; a spacer disposed under the bank layer; an auxiliary layer disposed in the dummy opening of the bank layer, including the same material as the spacer, and having a thickness smaller than a thickness of the bank layer; a second base substrate facing the first base substrate: a display element layer disposed on the second base substrate; and a filling layer filling a gap between the first base substrate and the second base substrate.

In an embodiment, the thickness of the auxiliary layer may be smaller than a thickness of the color conversion layer.

In an embodiment, the filling layer may be disposed under the auxiliary layer in the dummy opening.

In an embodiment, a distance between the auxiliary layer and the display element layer may have a range of about 8 micrometers or more.

In an embodiment, the spacer may contact the display element layer.

In an embodiment, each of the spacer and the auxiliary layer may include an organic photoresist material.

In an embodiment, a thickness of the spacer may be smaller than the thickness of the auxiliary layer.

In an embodiment, the filling layer may include an organic material.

In an embodiment, the display device may further include a capping layer disposed under the bank layer and the color conversion layer.

In an embodiment, the capping layer may cover the bank layer and the color conversion layer, and may be disposed in the dummy opening.

In an embodiment, the auxiliary layer may be disposed under the capping layer in the dummy opening.

In an embodiment, the spacer may be disposed under the capping layer.

In an embodiment, the display element layer may include a transistor disposed on the second base substrate and a light emitting diode connected to the transistor.

In an embodiment, the light emitting diode may overlap the pixel opening and may be spaced apart from the dummy opening in a plan view.

In an embodiment, a thickness of the color conversion layer may be smaller than the thickness of the bank layer.

In an embodiment, the display device may further include a color filter layer disposed between the first base substrate and the bank layer and a low-refractive index layer disposed between the color filter layer and the bank layer.

In a display device according to embodiments, manufacturing cost of the display device can be reduced by disposing the auxiliary layer including the same material as the spacer in the dummy opening. Specifically, by disposing the auxiliary layer in the dummy opening, the filling layer may be less than the volume of the auxiliary layer in the dummy opening. Accordingly, material consumption of the filling layer can be reduced, manufacturing cost of the display device can be reduced, and manufacturing efficiency of the display device can be effectively improved.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of the present disclosure.

FIG. 2 is a cross-sectional view taken along line I-I′ of FIG. 1.

FIG. 3 is an enlarged plan view of area A of FIG. 1.

FIG. 4 is a cross-sectional view taken along line II-II′ of FIG. 3.

FIG. 5 is a cross-sectional view taken along line III-III′ of FIG. 3.

### DETAILED DESCRIPTION

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Hereinafter, a display device according to embodiments of the present disclosure will be explained in detail with reference to the accompanying drawings. The same reference numerals are used for the same components in the drawings, and redundant descriptions of the same components will be omitted.

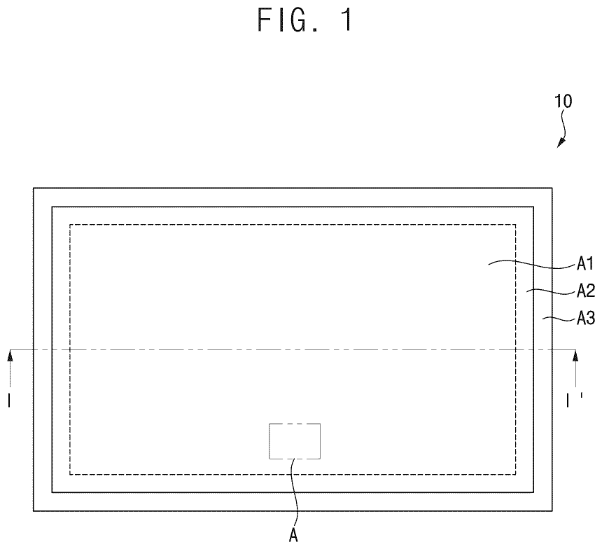

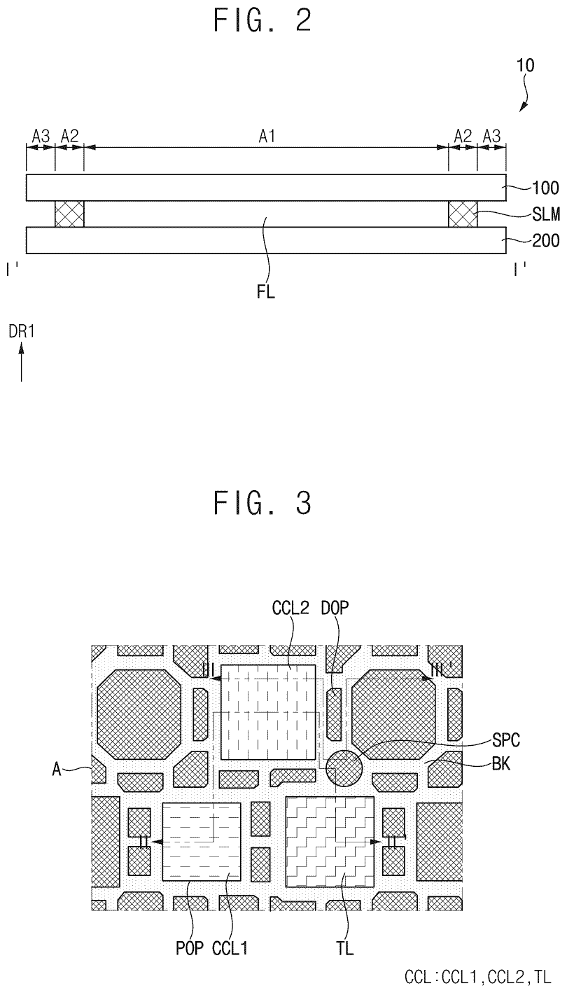

FIG. 1 is a plan view illustrating a display device according to an embodiment of the present disclosure. FIG. 2 is a cross-sectional view taken along line I-I′ of FIG. 1. Here, the plan view is a view in a thickness direction (i.e., DR1 in FIG. 2) of a color conversion substrate 100.

Referring to FIGS. 1 and 2, the display device 10 may include a color conversion substrate 100, a sealing member SLM, and an array substrate 200. The color conversion substrate 100 may face the array substrate 200. The color conversion substrate 100 may be positioned in a first direction DR1 from the array substrate 200. For example, the first direction DR1 may be a front direction of the display device 10 from the array substrate 200 (i.e., normal direction of a major surface plane of the array substrate 200).

The sealing member SLM may be disposed between the array substrate 200 and the color conversion substrate 100. The sealing member SLM may couple the array substrate 200 and the color conversion substrate 100.

The display device 10 may include a first area A1 where an image is displayed, a second area A2 surrounding the first area A1, and a third area A3 surrounding the second area A2. For example, the first area A1 may be a display area, and the second area A2 and the third area A3 may be non-display areas. Specifically, the second area A2 may be a sealing area, and the third area A3 may be an outer area.

The color conversion substrate 100 may include a color conversion layer (e.g., a color conversion layer CCL of FIG. 3). The color conversion layer may be disposed in the first area A1 and may convert a wavelength of light generated from the light emitting diodes of the array substrate 200. The color conversion substrate 100 may further include a color filter layer that transmits light of a specific color.

The array substrate 200 may include a plurality of pixels and may be referred to as a display substrate. The pixels may be disposed in the first area A1 of the array substrate 200. Each of the pixels may include a transistor and a light emitting diode. The transistor may include at least one transistor. The light emitting diode may generate light according to a driving signal. In an embodiment, for example, the light emitting diode may be an inorganic light emitting diode or an organic light emitting diode.

The sealing member SLM may be disposed between the array substrate 200 and the color conversion substrate 100 and may be disposed in the second area A2. For example, the sealing member SLM may be disposed in the second area A2 between the array substrate 200 and the color conversion substrate 100 so as to surround the first area A1 in a plan view.

The filling layer FL may be disposed between the array substrate 200 and the color conversion substrate 100. The filling layer FL may fill a gap between the array substrate 200 and the color conversion substrate 100. In an embodiment, for example, the filling layer FL may act as a buffer against external pressure applied to the display device 10. For example, the filling layer FL may maintain a gap between the array substrate 200 and the color conversion substrate 100. However, the present disclosure is not limited thereto.

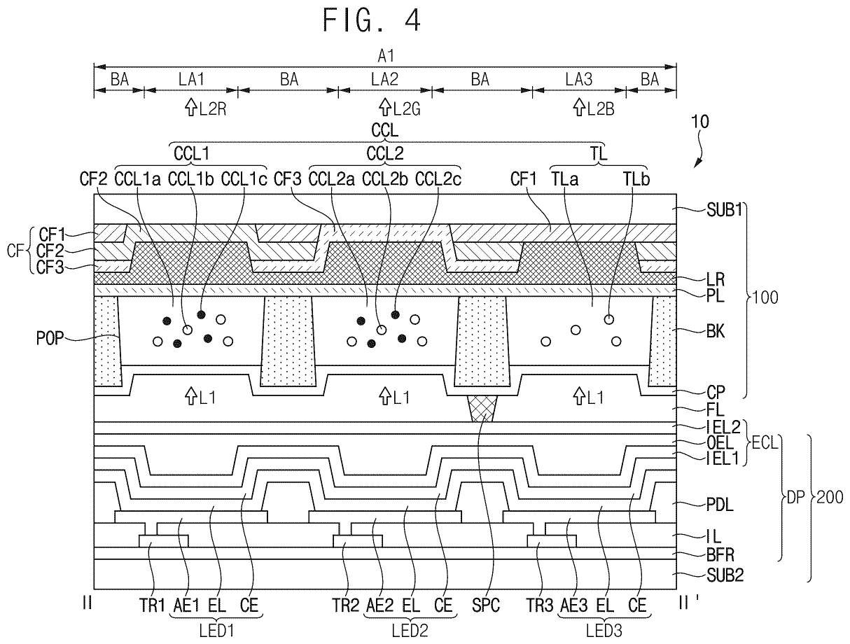

FIG. 3 is an enlarged plan view of area A of FIG. 1. FIG. 4 is a cross-sectional view taken along line II-II′ of FIG. 3.

For example, FIG. 3 may be a plan view of the color conversion substrate 100 of FIG. 2.

Referring to FIGS. 1, 2, 3, and 4, the first area A1 may include a light emitting area and a light blocking area BA. Light L1 (hereinafter referred to as incident light) generated from the array substrate 200 and incident to the color conversion substrate 100 may be emitted to the outside through the light emitting area. The light emitting area may include first, second, and third light emitting areas LA1, LA2, and LA3 for emitting light of different colors. In an embodiment, for example, a first transmitted light L2R having red color may be emitted from the first light emitting area LA1, a second transmitted light L2G having green color may be emitted from the second light emitting area LA2, and a third transmitted light L2B having blue color may be emitted from the third light emitting area LA3.

In an embodiment, the first, second, and third light emitting areas LA1, LA2, and LA3 may be spaced apart from each other in the plan view and may be arranged to repeat each other. The light blocking area BA may surround the first, second, and third light emitting areas LA1, LA2, and LA3 in the plan view. In an embodiment, for example, the light blocking area BA may have a grid shape in the plan view.

In an embodiment, the color conversion substrate 100 may include the sealing member SLM, a first base substrate SUB1, a color filter layer CF, a bank layer BK, the color conversion layer CCL, a low refractive index layer LR, a protective layer PL, a capping layer CP, a spacer SPC, and an auxiliary layer AL.

The first base substrate SUB1 may include the first area A1, the second area A2, and the third area A3 as the display device 10 includes the first area A1, the second area A2, and the third area A3.

The first base substrate SUB1 may be an insulating substrate made of a transparent material. The first base substrate SUB1 may include glass or plastic.

The color filter layer CF may be disposed under the first base substrate SUB1. For example, the color filter layer CF may include a first color filter pattern CF1, a second color filter pattern CF2, and a third color filter pattern CF3.

In an embodiment, each of the first color filter pattern CF1, the second color filter pattern CF2, and the third color filter pattern CF3 may be disposed to more overlap the light blocking area BA. That is, as illustrated in FIG. 3, the second color filter pattern CF2 may overlap the first light emitting area LA1 and the light blocking area BA, and may not overlap the second and third light emitting areas LA2 and LA3 in a plan view. The third color filter pattern CF3 may overlap the second light emitting area LA2 and the blocking area BA, and may not overlap the first and third light emitting areas LA1 and LA3 in a plan view. The first color filter pattern CF1 may overlap the third light emitting area LA3 and the blocking area BA, and may not overlap the first and second light emitting areas LA1 and LA2 in a plan view. In this case, in the blocking area BA, parts of the first, second, and third color filter patterns CF1, CF2, and CF3 may overlap each other in the first direction DR1 (i.e., thickness direction). Accordingly, color mixing between the adjacent first, second, and third light emitting areas LA1, LA2, and LA3 can be prevented.

The color filter layer CF may be disposed under the first base substrate SUB1. A part of the color filter layer CF overlapping the second area A2 and the third area A3 may serve as a light blocking member. In the second area A2 and the third area A3, the third color filter pattern CF3, the second color filter pattern CF2, and the first color filter pattern CF1 may overlap in the first direction DR1. Accordingly, in the second area A2 and the third area A3, the color filter layer CF can effectively block light traveling in the first direction DR1.

In an embodiment, for example, in the second area A2 and the third area A3, the first color filter pattern CF1 may be disposed under the first base substrate SUB1, the second color filter pattern CF2 may be disposed under the first color filter pattern CF1, and the third color filter pattern CF3 may be disposed under the second color filter pattern CF2. However, in the embodiments according to the present disclosure, the arrangement order is not limited thereto.

In the second area A2 and the third area A3, the color filter layer CF can prevent circuit structures such as lines, driving circuits, or the like disposed in the second area A2 of the color conversion substrate 100 from being visually recognized from the outside of the display device 10. In addition, the color filter layer CF can prevent a light leakage phenomenon in which light reflected from the circuit structure or emitted from the first area A1 is emitted through the second area A2 and the third area A3 of the first base substrate SUB1.

The bank layer BK may be disposed under the color filter layer CF. The bank layer BK may define a plurality of openings therein. In an embodiment, for example, as illustrated in FIG. 3, the openings of the bank layer BK may expose the first, second, and third light emitting areas LA1, LA2, and LA3, respectively. The bank layer BK may form a space capable of accommodating ink in the process of forming the color conversion layer CCL. In an embodiment, for example, the bank layer BK may entirely overlap the light blocking area BA and may have a grid shape in the plan view.

Specifically, the bank layer BK may define a pixel opening POP and a dummy opening DOP. The pixel opening POP may define each of the first, second, and third light emitting areas LA1, LA2, and LA3. The color conversion layer CCL may be disposed in the pixel opening POP. The dummy opening DOP may be disposed adjacent to the pixel opening POP and may surround the pixel opening POP. The dummy opening DOP may accommodate ink misplaced when the color conversion layer CCL is manufactured.

The pixel opening POP may have an octagonal or smaller polygonal shape, or a circular shape. That is, the pixel opening POP may have one of a circular shape, a triangular shape, a rectangular shape, a pentagonal shape, a hexagonal shape, a heptagonal shape, and an octagonal shape.

In an embodiment, the bank layer BK may include an organic material. In an embodiment, the bank layer BK may further include a light blocking material. In an embodiment, for example, at least a part of the bank layer BK may include a light blocking material such as black pigment, dye, carbon black, or the like.

The low refractive index layer LR may be disposed under the color filter layer CF. The low refractive index layer LR may have a lower refractive index than the color conversion layer CCL. The low refractive index layer LR can increase light extraction efficiency and increase luminance and lifetime of the display device 10. The low refractive index layer LR may include an organic material.

The protective layer PL may be disposed under the low refractive index layer LR. In an embodiment, for example, the protective layer PL may cover the low refractive index layer LR. The protective layer PL may include an inorganic material.

The color conversion layer CCL may be disposed under the protective layer PL. The color conversion layer CCL may be disposed in the pixel openings POP of the bank layer BK. The color conversion layer CCL may convert the color of the incident light L1. In addition, the thickness of the color conversion layer CCL may be smaller than the thickness of the bank layer BK. A bottom surface of the color conversion layer CCL may be located higher than a bottom surface of the bank layer BK. Here, the thickness is measured in the first direction DR1.

The color conversion layer CCL may include color conversion portions spaced apart from each other on the lower surface of the protective layer PL. In an embodiment, the color conversion layer CCL may include a first color conversion portion CCL1, a second color conversion portion CCL2, and a transmission portion TL. The first color conversion portion CCL1, the second color conversion portion CCL2, and the transmission portion TL may be disposed in the first area A1 under the color filter layer CF, and may overlap the first, second, and third light emitting areas LA1, LA2, and LA3, respectively in the plan view. For example, the first color conversion portion CCL1, the second color conversion portion CCL2, and the transmission portion TL may be disposed in the pixel openings POP of the bank layer BK, respectively.

The first color conversion portion CCL1 may overlap the first light emitting area LA1. The first color conversion portion CCL1 may convert the incident light L1 into the first transmitted light L2R having a red color. In an embodiment, for example, the first color conversion portion CCL1 may include a resin part CCL1a, a scattering body CCL1b, and a wavelength conversion particle CCL1c.

The scattering body CCL1b may increase an optical path by scattering the incident light L1 without substantially changing the wavelength of the incident light L1 incident on the first color conversion portion CCL1. The scattering body CCL1b may include a metal oxide or an organic material. Alternatively, the scattering body CCL1b may be omitted.

In an embodiment, the wavelength conversion particle CCL Ic may include a quantum dot. The quantum dot may be defined as a semiconductor material having nanocrystals. The quantum dot may have a specific band gap depending on its composition and size. Accordingly, the quantum dots may absorb the incident light L1 and emit light having a different wavelength from the wavelength of the incident light L1. In an embodiment, for example, the quantum dot may have a diameter of about 100 nanometers (nm) or less, and specifically, the quantum dot may have a diameter of about 1 nm to about 20 nm. For example, the wavelength conversion particle CCL1c of the first color conversion portion CCL1 may include a quantum dot that absorbs the incident light L1 and emits red light.

The scattering body CCL1b and the wavelength conversion particle CCL1c may be disposed in the resin part CCL1a. In an embodiment, for example, the resin part CCL1a may include an epoxy-based resin, an acrylic-based resin, a phenol-based resin, a melamine-based resin, a cardo-based resin, an imide-based resin, or the like.

The first color conversion portion CCL1 may convert the incident light L1 to emit the first transmitted light L2R having red color. The incident light L1 not converted by the first color conversion portion CCL1 may be blocked by the second color filter pattern CF2. Accordingly, in the first light emitting area LA1, the first transmission light L2R having red color may pass through the first base substrate SUB1 and be emitted to the outside (i.e., in the first direction DR1).

The second color conversion portion CCL2 may overlap the second light emitting area LA2. The second color conversion portion CCL2 may convert the incident light L1 into second transmitted light L2G having a green color. In an embodiment, for example, the second color conversion portion CCL2 may include a resin part CCL2a, a scattering body CCL2b, and a wavelength conversion particle CCL2c. The resin part CCL2a and the scattering body CCL2b of the second color conversion portion CCL2 may be substantially the same as or similar to the resin part CCL1a and the scattering body CCL1b of the first color conversion portion CCL1.

In an embodiment, for example, the wavelength conversion particles CCL2c of the second color conversion portion CCL2 may include quantum dot that absorb the incident light L1 and emit green light. Accordingly, the second color conversion portion CCL2 may convert the incident light L1 to emit the second transmitted light L2G having a green color. The incident light L1 not converted by the second color conversion portion CCL2 may be blocked by the third color filter pattern CF3. Accordingly, in the second light emitting area LA2, the second transmission light L2G having green color may pass through the first base substrate SUB1 and be emitted to the outside (i.e., in the first direction DR1).

The transmission portion TL may overlap the third light emitting area LA3 in a plan view. The transmitting portion TL may transmit the incident light L1 to emit the third transmitted light L2B. In an embodiment, for example, the transmission portion TL may include a resin part TLa and a scattering body TLb. The resin part TLa and the scattering body TLb of the transmission portion TL may be substantially the same as or similar to the resin part CCL1a and the scattering body CCL1b of the first color conversion portion CCL1.

However, the present invention is not limited thereto, and the transmitting portion TL may convert the incident light L1 into the third transmitted light L2B having a blue color in another embodiment. In this case, the transmission portion TL may further include wavelength conversion particles including quantum dot that absorb the incident light L1 and emit blue light.

Some of the incident light L1 may be blocked by the first color filter pattern CF1. Accordingly, in the third light emitting area LA3, the third transmitted light L2B having blue color may pass through the first base substrate SUB1 and be emitted to the outside (i.e., in the first direction DR1).

As the first, second, and third transmitted lights L2R, L2G, and L2B emitted to the outside through the first base substrate SUB1 are combined in the first, second, and third light emitting areas LA1, LA2, and LA3, the image may be displayed in the first area A1.

The capping layer CP may be disposed under the bank layer BK, the color conversion layer CCL, and the protective layer PL. The capping layer CP may protect the color conversion layer CCL from oxygen, moisture, foreign substances, or the like. In an embodiment, for example, the capping layer CP may cover the protective layer PL, the bank layer BK, and the color conversion layer CCL.

The spacer SPC may be disposed under the bank layer BK. That is, the spacer SPC may be disposed on the lower surface of the bank layer BK. Specifically, the spacer SPC may be disposed under the capping layer CP. The spacer SPC may contact the array substrate 200. Specifically, the spacer SPC may contact a display element layer DP, which will be described later. The spacer SPC may contact the display element layer DP and maintain a gap between the color conversion substrate 100 and the array substrate 200.

The spacer SPC may include an organic material. For example, the spacer SPC may include an organic photoresist material. However, the present disclosure is not limited thereto.

In an embodiment, the array substrate 200 may include a second base substrate SUB2 and the display element layer DP.

The second base substrate SUB2 may face the first base substrate SUB1. The second base substrate SUB2 may include the first area A1, the second area A2, and the third area A3 as the display device 10 includes the first area A1, the second area A2, and the third area A3.

The display element layer DP may be disposed on the second base substrate SUB2. The display element layer DP may include a buffer layer BFR, first, second, and third transistors TR1, TR2, and TR3, an insulating layer IL, a pixel definition layer PDL, first, second, and third light emitting diodes LED1, LED2, and LED3, and an encapsulation layer ECL.

The buffer layer BFR may be disposed on the second base substrate SUB2. The buffer layer BFR may prevent impurities such as oxygen and moisture from diffusing onto the second base substrate SUB2 through the second base substrate SUB2. The buffer layer BFR may include an inorganic material such as a silicon compound, a metal oxide, or the like. The buffer layer BFR may have a single-layer structure or a multi-layer structure including a plurality of insulating layers.

The first, second, and third transistors TR1, TR2, and TR3 may be disposed in the first area A1 on the buffer layer BFR. The channel layer of the transistor may include an oxide semiconductor, a silicon semiconductor, or an organic semiconductor. In an embodiment, for example, the oxide semiconductor may include at least one oxide of indium (In), gallium (Ga), tin (Sn), zirconium (Zr), vanadium (V), hafnium (Hf), cadmium (Cd), germanium (Ge), chromium (Cr), titanium (Ti), zinc (Zn), or the like. The silicon semiconductor may include amorphous silicon, polycrystalline silicon, or the like.

The insulating layer IL may cover the first, second, and third transistors TR1, TR2, and TR3. The insulating layer IL may include a combination of an inorganic insulating layer and an organic insulating layer.

The first, second, and third light emitting diodes LED1, LED2, and LED3 may be disposed on the insulating layer IL. The first, second, and third light emitting diodes LED1, LED2, and LED3 may be connected to the first, second, and third transistors TR1, TR2, and TR3, respectively. The first, second, and third light emitting diodes LED1, LED2, and LED3 may overlap the pixel openings POP and may be spaced apart from the dummy openings DOP in a plan view.

In an embodiment, for example, first, second, and third pixel electrodes AE1, AE2, and AE3 may be disposed on the insulating layer IL. Each of the first, second, and third pixel electrodes AE1, AE2, and AE3 may include a conductive material such as a metal, an alloy, a conductive metal nitride, a conductive metal oxide, a transparent conductive material, or the like. Each of the first, second, and third pixel electrodes AE1, AE2, and AE3 may have a single-layer structure or a multi-layer structure including a plurality of conductive layers.

The first, second, and third pixel electrodes AE1, AE2, and AE3 may be connected to the first, second, and third transistors TR1, TR2, and TR3 through contact holes defined in the insulating layer IL, respectively.

The pixel defining layer PDL may be disposed on the first, second, and third pixel electrodes AE1, AE2, and AE3. The pixel defining layer PDL may include an organic material. The pixel defining layer PDL may define a pixel opening exposing at least a part of each of the first, second, and third pixel electrodes AE1, AE2, and AE3.

The light emitting layer EL may be disposed on the first, second, and third pixel electrodes AE1, AE2, and AE3 exposed by the pixel opening of the pixel defining layer PDL. In an embodiment, the light emitting layer EL may continuously extend over a plurality of pixels on the first area A1. In another embodiment, the light emitting layer EL may be separated from the light emitting layer of an adjacent pixel.

The light emitting layer EL may include at least one of an organic light emitting material and quantum dots. In an embodiment, the light emitting layer EL may generate blue light. However, embodiments of the present disclosure are not limited thereto. In another embodiment, the light emitting layer EL may generate red light or green light, or may generate lights having different colors according to pixels.

In an embodiment, for example, all of the light emitting layers EL may include an organic material for emitting blue light. In this case, the light emitting layer EL may be formed in multiple layers and may have a structure in which a plurality of blue organic light emitting layers are stacked. For example, the light emitting layer EL may have a structure in which three blue organic light emitting layers are stacked.

However, embodiments according to the present disclosure are not limited thereto, and the light emitting layer EL may have a structure in which a plurality of blue organic light emitting layers and an organic light emitting layer emitting light of different colors are stacked in another embodiment. For example, the light emitting layer EL may have a structure in which three blue organic light emitting layers and one green organic light emitting layer are stacked. In an embodiment, functional layers such as a hole injection layer, a hole transport layer, an electron transport layer, and an electron injection layer may be disposed on and/or under the light emitting layer EL.

The common electrode CE may be disposed on the light emitting layer EL. The common electrode CE may include a conductive material such as a metal, an alloy, a conductive metal nitride, a conductive metal oxide, a transparent conductive material, or the like. The common electrode CE may have a single-layer structure or a multi-layer structure including a plurality of conductive layers. In an embodiment, the common electrode CE may continuously extend on the first area A1 over the plurality of pixels.

The first pixel electrode AE1, the light emitting layer EL, and the common electrode CE may form the first light emitting diode LED1, the second pixel electrode AE2, the light emitting layer EL, and the common electrode CE may form the second light emitting diode LED2, and the third pixel electrode AE3, the light emitting layer EL, and the common electrode CE may form the third light emitting diode LED3.

The encapsulation layer ECL may be disposed on the common electrode CE. The encapsulation layer ECL may include at least one inorganic encapsulation layer and at least one organic encapsulation layer. In one embodiment, the encapsulation layer ECL may include a first inorganic encapsulation layer IEL1 disposed on the common electrode CE, an organic encapsulation layer OEL disposed on the first inorganic encapsulation layer IEL1, and a second inorganic encapsulation layer IEL2 disposed on the organic encapsulation layer OEL.

In an embodiment, the filling layer FL may fill a gap between the first base substrate SUB1 and the second base substrate SUB2. That is, the filling layer FL may fill a gap between the capping layer CP included in the color conversion substrate 100 and the encapsulation layer ECL included in the array substrate 200. The filling layer FL may include an organic material. In an embodiment, for example, the filling layer FL may include polyimide or acrylate.

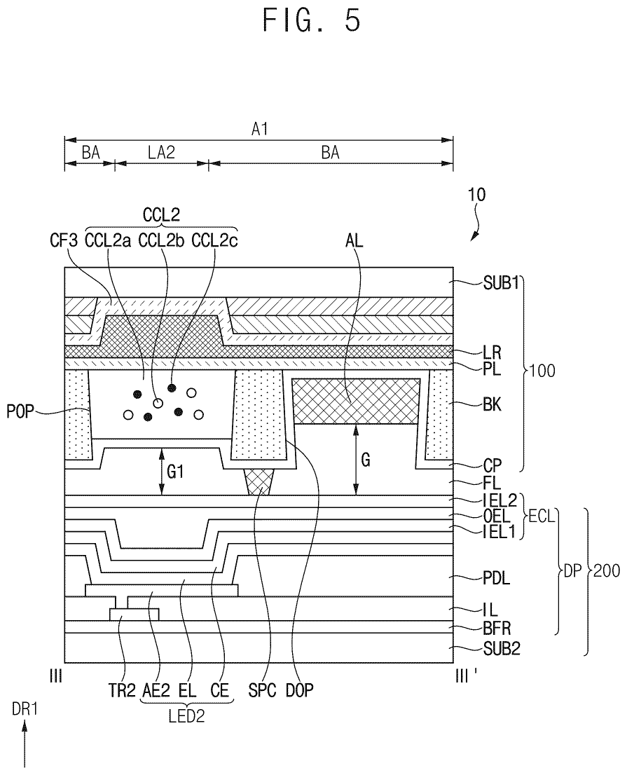

FIG. 5 is a cross-sectional view taken along line III-III′ of FIG. 3.

Referring further to FIG. 5, in an embodiment, the auxiliary layer AL may be disposed in the dummy opening DOP of the bank layer BK. Specifically, the capping layer CP may be disposed in the dummy opening DOP, and the auxiliary layer AL may be disposed under the capping layer CP in the dummy opening DOP.

The auxiliary layer AL may include the same material as the spacer SPC. The auxiliary layer AL may include an organic material. For example, the auxiliary layer AL may include an organic photoresist material. However, the present disclosure is not limited thereto.

In an embodiment, the thickness of the auxiliary layer AL may be smaller than the thickness of the bank layer BK. That is, the auxiliary layer AL may partially fill the inside of the dummy opening DOP. Accordingly, both the auxiliary layer AL and the filling layer FL may be disposed in the dummy opening DOP. That is, the filling layer FL may be disposed under the auxiliary layer AL in the dummy opening DOP.

In addition, the thickness of the auxiliary layer AL may be smaller than the thickness of the color conversion layer CCL in the first direction DR1. Therefore, a distance G between the auxiliary layer AL and the encapsulation layer ECL in the dummy opening DOP (i.e., height of a bottom surface of the auxiliary layer AL from a top surface of the encapsulation layer ECL in the first direction DR1 in the dummy opening DOP) may be greater than the distance G1 between the capping layer CP and the encapsulation layer ECL in the pixel opening POP (i.e., height of a bottom surface of the capping layer CP from a top surface of the encapsulation layer ECL in the first direction DR1 in the pixel opening POP). Even when a foreign material flows into the dummy opening DOP, damage to the auxiliary layer AL, the capping layer CP, and the encapsulation layer ECL due to the foreign material can be effectively prevented.

In an embodiment, the distance G between the auxiliary layer AL and the display element layer DP may have a range of about 8 micrometers or more. In this case, the distance G between the auxiliary layer AL and the display element layer DP may be the same as the distance between the auxiliary layer AL and the encapsulation layer ECL. In an embodiment, for example, a foreign material having a size of about 8 micrometers or more may be removed during the manufacturing process of the display device 10. Therefore, only foreign materials having a size of less than about 8 micrometers may exist after the manufacturing process of the display device 10. Therefore, when the distance G between the auxiliary layer AL and the display element layer DP is about 8 micrometers or more, even if the remaining foreign material having a size of less than about 8 micrometers exists between the auxiliary layer AL and the display element layer DP, the problem of damage to the auxiliary layer AL and the encapsulation layer ECL due to the foreign material can be effectively prevented.

In an embodiment, the thickness of the spacer SPC may be smaller than the thickness of the auxiliary layer AL. In addition, the auxiliary layer AL may be formed simultaneously with the spacer SPC. Accordingly, the auxiliary layer AL and the spacer SPC may be simultaneously formed using a halftone mask or a slit mask.

In an embodiment, manufacturing cost of the display device 10 can be reduced by disposing the auxiliary layer AL including the same material as the spacer SPC in the dummy opening DOP. Specifically, by disposing the auxiliary layer AL in the dummy opening DOP, the filling layer FL may be less than the volume of the auxiliary layer AL in the dummy opening DOP. Accordingly, material consumption of the filling layer FL can be reduced, manufacturing cost of the display device 10 can be reduced, and manufacturing efficiency of the display device 10 can be effectively improved.

The present disclosure can be applied to various display devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present invention. Accordingly, all such modifications are intended to be included within the scope of the present invention as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A color conversion substrate comprising:
a base substrate;
a bank layer disposed under the base substrate and defining a pixel opening and a dummy opening adjacent to the pixel opening;
a color conversion layer disposed in the pixel opening of the bank layer;
a spacer disposed under the bank layer; and
an auxiliary layer disposed in the dummy opening of the bank layer, including a same material as the spacer, and having a thickness smaller than a thickness of the bank layer.

2. The color conversion substrate of claim 1, wherein the thickness of the auxiliary layer is smaller than a thickness of the color conversion layer.

3. The color conversion substrate of claim 1, wherein each of the spacer and the auxiliary layer includes an organic photoresist material.

4. The color conversion substrate of claim 1, further comprising:
a color filter layer disposed between the base substrate and the bank layer; and
a low-refractive index layer disposed between the color filter layer and the bank layer.

5. A display device comprising:
a first base substrate;
a bank layer disposed under the first base substrate and defining a pixel opening and a dummy opening adjacent to the pixel opening;
a color conversion layer disposed in the pixel opening of the bank layer;
a spacer disposed under the bank layer;
an auxiliary layer disposed in the dummy opening of the bank layer, including a same material as the spacer, and having a thickness smaller than a thickness of the bank layer;
a second base substrate facing the first base substrate;
a display element layer disposed on the second base substrate; and
a filling layer filling a gap between the first base substrate and the second base substrate.

6. The display device of claim 5, wherein the thickness of the auxiliary layer is smaller than a thickness of the color conversion layer.

7. The display device of claim 5, wherein the filling layer is disposed under the auxiliary layer in the dummy opening.

8. The display device of claim 5, wherein a distance between the auxiliary layer and the display element layer has a range of about 8 micrometers or more.

9. The display device of claim 5, wherein the spacer contacts the display element layer.

10. The display device of claim 5, wherein each of the spacer and the auxiliary layer includes an organic photoresist material.

11. The display device of claim 5, wherein a thickness of the spacer is smaller than the thickness of the auxiliary layer.

12. The display device of claim 5, wherein the filling layer includes an organic material.

13. The display device of claim 5, further comprising:
a capping layer disposed under the bank layer and the color conversion layer.

14. The display device of claim 13, wherein the capping layer covers the bank layer and the color conversion layer, and is disposed in the dummy opening.

15. The display device of claim 13, wherein the auxiliary layer is disposed under the capping layer in the dummy opening.

16. The display device of claim 13, wherein the spacer is disposed under the capping layer.

17. The display device of claim 5, wherein the display element layer includes:
a transistor disposed on the second base substrate; and
a light emitting diode connected to the transistor.

18. The display device of claim 17, wherein the light emitting diode overlaps the pixel opening and is spaced apart from the dummy opening in a plan view.

19. The display device of claim 5, wherein a thickness of the color conversion layer is smaller than the thickness of the bank laver.

20. The display device of claim 5, further comprising:
a color filter layer disposed between the first base substrate and the bank layer; and
a low-refractive index layer disposed between the color filter layer and the bank layer.
